(19) United States
(12) Patent Application Publication
(10) Pub. No.: US 2014/0232451 A1
(43) Pub. Date: Aug. 21, 2014

(54) THREE TERMINAL SEMICONDUCTOR DEVICE WITH VARIABLE CAPACITANCE

(71) Applicant: QUALCOMM INCORPORATED, San Diego, CA (US)

(72) Inventor: Ranadeep Dutta, San Diego, CA (US)

(73) Assignee: QUALCOMM INCORPORATED, San Diego, CA (US)

(21) Appl. No.: 13/770,005

(22) Filed: Feb. 19, 2013

(51) Int. Cl. H01L 29/93; G05B 99/00

(52) U.S. Cl. CPC H01L 29/93; G05B 99/00
USPC 327/535; 257/312

(57) ABSTRACT

Methods and apparatus for implementing variable, e.g., tunable, 3 terminal capacitance devices are described. In various embodiments vertical control pillars spaced apart from one another extend in a well having an opposite polarity than the polarity of the control pillars. The control pillars are arranged in a line that extends parallel to but between a deep trench gate and a well pickup. By varying the voltage applied to the control pillars the size of the depletion zone around the pillars can be varied resulting in a change in capacitance between the trench gate and pickup terminal connected to the well pickup. The generally vertical nature of the control pillars facilities control over a wide range of voltages while allowing for manufacturing using common semiconductor manufacturing steps making the device easy to implement on a chip with other semiconductor devices.

### FIELD

Methods and apparatus relating to electronic semiconductor devices and, more particularly, to devices whose capacitance between two terminals can be varied by the application of a control voltage to a third terminal, are described.

### BACKGROUND

Various electronic communications systems such as the tunable antenna systems benefit significantly from variable, e.g., tunable, capacitors. Since the capacitance of a tunable capacitor can be varied, an antenna system using such a capacitor can be used for different frequency ranges and/or controlled to exhibit different characteristics, by changing the capacitance of the tunable capacitor. Thus, tunable capacitors can be used to reduce or eliminate the need for multiple antenna systems by allowing tuning to be performed thereby allowing a single antenna system to operate in a variety of different frequency bands and/or by reducing the size, cost, and/or complexity of antenna systems as compared to antenna system which used fixed (non-tunable) capacitors.

In many applications tunable capacitors needs to be able to sustain large voltage swings (e.g., +/−35V) which may be present in an antenna system. Such large voltage swings generally require use of a thick oxide (of the order of ˜1000-2000 A) when the capacitor is implemented as a semiconductor device. Unfortunately, the use of such a thick oxide kills or substantially reduces the tuneability of standard CMOS (complementary metal oxide semiconductor) based accumulation varactors where the tuneability maybe expressed as a ratio of a devices maximum capacitance (Cmax) divided by its minimum capacitance (Cmin). That is, for thick oxide devices the tuning ratio approaches 1 (Cmax/Cmin˜1), making the use of thick oxide CMOS varactors undesirable or even unusable as variable capacitors for many applications.

The relation between the capacitance and voltage of a MOS (metal oxide semiconductor) capacitor can be appreciated from the following equation:

$$C ( V ) = \frac{{∈}_{ox}}{{T}_{ox} + ( \frac{{∈}_{ox}}{{∈}_{si}} ) \cdot W ( V )}$$

where C(V) is the capacitance as a function of voltage, Tₒₓ is the oxide thickness, εₒₓ is the oxide permittivity, εₛᵢ is the silicon (Si) permittivity, W(V) is the depletion width as a function of voltage.

Thus, the tuning ratio, which is expressed as Cmax/Cmin, approaches 1 as Tₒₓ increases thereby making use of thick oxide undesirable for applications where high tuning ratio is desired.

In the past few years some attempts have been made to address some of the above discussed issues and manufacture capacitor devices with somewhat improved tunability such as the 3 terminal gated varactor with improved tuning range illustrated in FIG. 1. The 3 terminal gated varactor 100 shown in FIG. 1 has a structure similar to a standard PMOS transistor, with the exception that the semiconductor material of the drain terminal is replaced by N+ in place of the P type semiconductor material which is normally used in the PMOS. The 3 terminal gated varactor 100 includes three terminal i.e., a source terminal 104, a gate terminal 106 and a drain terminal 108. Application of a positive drain potential expands the depletion layer under the gate terminal decreasing the capacitance further. Thus, the known varactor 100 suffers from a relatively limited capacitance range making it less than ideal for many applications.

In view of the above discussion it should be appreciated that there is a need for variable, e.g., tunable, capacitors with high tunability and having the capability to withstand large voltage swings. While not critical, it is desirable that new tunable capacitors can be integrated with standard semiconductor fabrication processing flows without adding much complexity and/or significantly increasing the cost of semiconductor devices and/or systems incorporating new tunable capacitors.

### SUMMARY

Methods and apparatus relating to variable three terminal capacitance devices, e.g., tunable capacitors, that can be implemented on a semiconductor material are described.

In various embodiments vertical control pillars spaced apart from one another extend in a well having an opposite polarity than the polarity of the control pillars. The control pillars are arranged in a line that extends parallel to but between a deep trench gate and a well pickup. By varying the voltage applied to the control pillars the size of the depletion zone around the pillars can be varied resulting in a change in capacitance between the trench gate and pickup terminal connected to the well pickup. The generally vertical nature of the control pillars facilities control over a wide range of voltages while allowing for manufacturing using common semiconductor manufacturing steps making the device easy to implement on a chip with other semiconductor devices,

In various implementations capacitance between two terminals of the device can be varied by the application of a control voltage to a third terminal, e.g. the control pillar terminal, of the device.

In addition to describing the device, the present application also describes methods of fabricating such variable capacitance semiconductor devices and using such devices, e.g., as apart of an electronic circuit. The variable capacitance devices can be implemented using relatively conventional semiconductor manufacturing techniques and/or steps thereby allowing the devices to be used and integrated into a large number of devices, e.g., chips, intended to support a wide range of operations.

In at least some embodiments the variable capacitance device supports a wider tuning range and/or higher voltages than some known semiconductor based variable capacitance devices.

In various embodiments, a tunable capacitor includes a substrate, a trench gate supported by said substrate with the trench gate having a first, e.g., deep, depth and extending in a first direction. The tunable capacitor also includes a first well of a first polarity where the first well extends in the first direction parallel to the trench gate and a first well pickup of said first polarity adjacent said first well and extending in the first direction. The trench gate may, and in some embodiments is, implemented by filling a deep well extending down to a buried oxide layer that covers the substrate or actually extends into the buried oxide layer that covers the substrate. The tunable capacitor includes at least a first plurality of depletion control pillars of a second polarity positioned in said first well between the trench gate and a first well pickup. Thus, the pillars may stand vertically, spaced apart from each other in a line which extends between a sidewall of the well pickup and a sidewall of the trench gate. In various embodiments, second polarity is different from the first polarity, e.g., the polarity of the control pillars is different from the polarity of the trench gate and well pickup. For example in some embodiments the trench gate has a negative polarity and is formed of an N+ doped poly material while the control pillars in such an exemplary embodiment are formed of a P+ doped material.

The terminals of the exemplary controllable capacitance devices include a first, e.g., well pickup terminal, that is in electrical contact with the well pickup, a second, e.g., control terminal, in contact with the control pillars, and a third terminal, e.g., a gate terminal in contact with the gate material forming the trench gate. The control pillars may, and in some embodiments are, arranged spaced apart from one another in a line extending in a first direction, e.g., a direction extending parallel to the sidewall of the trench gate and parallel to the sidewall of the well pickup.

In various embodiments the depletion control pillars are taller than they are wide and are arranged at or approximately halfway between the sidewall of the trench gate and the sidewall of the well pickup. Thus the height of depletion control pillars in various embodiments is greater than their width.

The tunable 3 terminal capacitors fabricated using the novel approach described herein offer the possibility of a higher tuning ratio than is possible with conventional CMOS varactors of the type described in the background section of the application. Various embodiments are compatible with CMOS, BiCMOS, BCD process flows on SOI or bulk substrates. In addition at least some embodiments allow for tunable capacitors with high tuneability even with thick oxide implementations.

While various embodiments have been discussed in the summary above, it should be appreciated that not necessarily all embodiments include the same features and some of the features described above are not necessary but can be desirable in some embodiments. Numerous additional features, embodiments and benefits of various embodiments are discussed in the detailed description which follows.

### BRIEF DESCRIPTION OF THE FIGURES

FIG. 1 illustrates a known 3 terminal variable capacitor.

FIG. 2 illustrates a left to right cross section of an exemplary electronic semiconductor device which can be used as a variable capacitor and which can be fabricated using an exemplary method in accordance with some embodiments.

FIG. 3 illustrates a top view of the exemplary electronic semiconductor device of FIG. 2 if sliced along the horizontal plane and then viewed from the top.

FIG. 4 illustrates an alternative embodiment to the FIG. 2 example which has a similar structure to that of the device shown in FIG. 2 but with N (negative) rather than a positive (P) substrate.

FIG. 5 illustrates an alternative three terminal semiconductor device which can be used as a variable capacitor implemented using a thick SOI base.

FIG. 6 shows another exemplary embodiment but using bulk SI instead of thick SOI.

FIG. 7 is a drawing showing a Capacitance versus Voltage (VSB) plot for a NMOS-N Well Varactor.

FIG. 8 is a drawing illustrating a Capacitance versus Voltage (depletion control voltage) plot for an exemplary semiconductor device, e.g., tunable depletion control capacitor, in accordance with an exemplary embodiment.

FIG. 9 is a flowchart illustrating an exemplary method of controlling a device, in accordance with one exemplary embodiment.

FIG. 10 illustrates an exemplary communications device that uses an exemplary tunable capacitor implemented in accordance with some embodiments.

### DETAILED DESCRIPTION

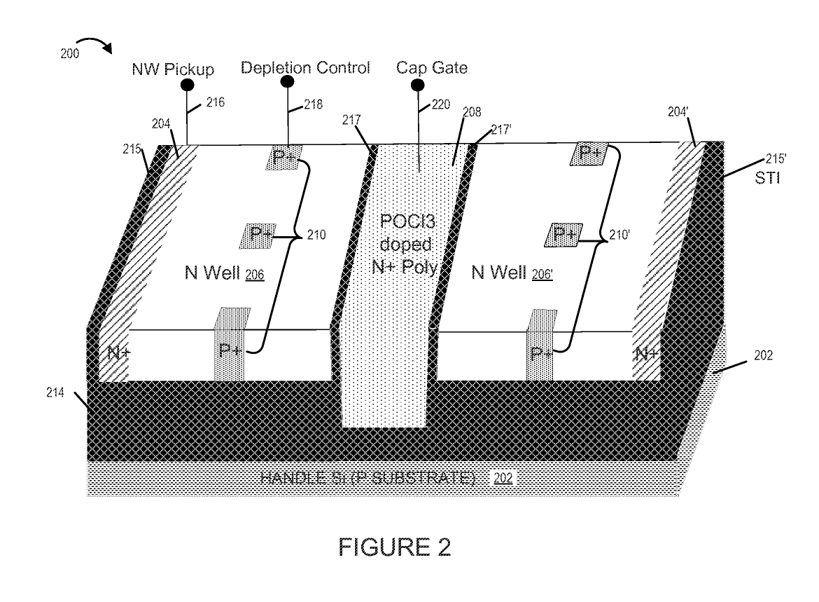

FIG. 2 illustrates the structure of an exemplary electronic semiconductor device 200, e.g., a tunable 3 terminal depletion control capacitor implemented in accordance with one exemplary embodiment. The three terminals of the device include an N well (NW) pickup terminal 216, a depletion control terminal 218 and a capacitor gate terminal 220. A voltage applied to the depletion control terminal which can be measured relative to the NW pickup terminal 216 controls the capacitance between the capacitor gate terminal 220 and the NW pickup. Accordingly, by varying the voltage applied to the depletion control terminal 218 the capacitance can be varied. A relatively wide range of voltages can be applied to the depletion control terminal 218 with the applied voltage ranging, in some embodiments by at least +/−35 volts for a total voltage range of 70 volts or even more. While the +/−35 volt range is supported in some embodiments in other embodiments smaller and/or larger voltage ranges are supported and used.

As illustrated the exemplary three terminal depletion control capacitor device 200 comprises a substrate 202 which in this embodiment is a P-type silicon (Si) substrate, however it should be appreciated that in other implementations other type of substrates with different polarity, e.g., N-type Si etc., may be used.

The device 200 further includes, a deep trench gate 208 supported by the substrate 202 and having a first depth and extending in a first direction. The capacitor gate terminal 220 is in electrical content with the contents of the deep trench gate. In the FIG. 2 example, the first direction extends from the front of the device 200 towards the back of the device 200 with the depth of the trench gate corresponding to the vertical direction which is perpendicular to said first direction. The device 200 further includes a first N (negative) well 206 extending in the first direction parallel to the trench gate 208, a first N well pickup 204 adjacent to the first N well 206 and extending in the first direction, and a first plurality of depletion control pillars 210 positioned in the first N well region 206 between the deep trench gate 208 and the first N well pickup 204. The N well pickup terminal 216 is in electrical contact with the N+ doped contents of the N well 204 while the depletion control terminal 218 is in electrical contact with the material forming the depletion control pillars 210. In some embodiments the pillars are highly positively doped (P+) pillars.

A liner oxide 214 is positioned on the sides of the trench gate 208 forming trench gate sidewalls separating the N+ (highly negatively doped) contents of the deep trench 208 from the N doped material of the N well 206. The liner oxide is used to form trench walls 217, 217′ in the form of a vertical layer which lines the sidewalls of the trench gate 208 and thus separates the material of trench gate 208 from the contents of the first and second N wells 206, 206′. The oxide material 214 is also used to form a layer over the P substrate 202 and to form silicon trench isolation walls 215, 215′. The liner material used for trench walls 217, 217′ may be the same oxide material used to line the substrate 202 or a different material. The gate material that fills the deep trench 208 and forms the gate electrode is PoCl3 doped poly silicon in some embodiments.

In the FIG. 2 example, it can be seen that the structure shown on the left side of the figure can be, and is, replicated on the right side to further increase the overall capacitance of the device. However, is should be appreciated that the variable capacitor 200 could be implemented and used without the duplication and/or extension of particular elements to the right side of the deep trench gate 208.

The device 200 includes, in addition to the left side components, on the right side of the a deep trench gate 208, a second N well region 206′ extending in the first direction parallel to the deep trench gate 208, a second N well pickup 204′ adjacent to the second N well region 206′ and extending in the first direction, and a second plurality of depletion control pillars 210′ positioned in the second N well region 206′ between the trench gate 208 and the second N well pickup 204′. In some embodiments the first plurality of depletion control pillars 210 is equal in number to the second plurality of depletion control pillars 210′ with all the depletion control pillars being interconnected. Similarly the N well pickup 204 in one such embodiment is interconnected with the N well pickup 204′ on the right side of the deep trench 208.

By mirroring the structure shown on the left side of the deep trench gate 208 to the right side, greater capacitance is achieved than would be achieved without such duplication. It should be appreciated that as an alternative or in addition to the replication of elements on the right side of the trench gate, the trench gate structure may be extended in the first direction to increase the capacitance of the device, e.g. by increasing the length in the first direction of the N well pickup, row of depletion control pillars 210, N well 206 and lined trench gate 208.

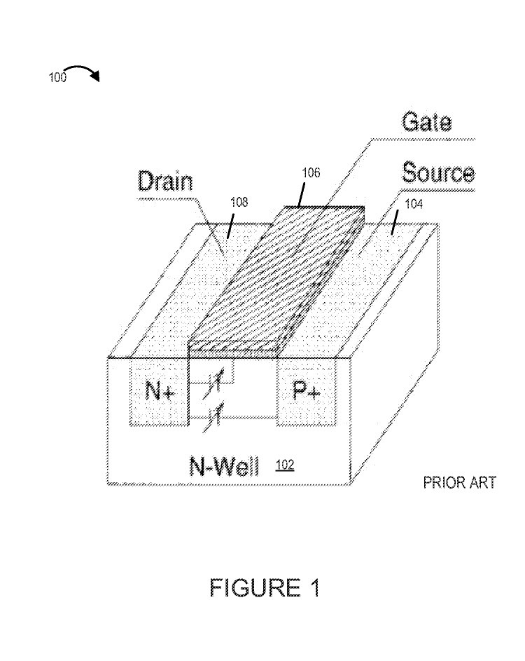

It should be appreciated from FIG. 2 that in the FIG. 2 embodiment the depletion control pillars 210, 210′ extend to the bottom of the N well 206, 206′ while the deep trench gate has a greater depth extending into the liner oxide 214 which separates the P substrate 202 from the elements supported by the substrate 202. It should also be appreciated that the depletion control pillars in the FIG. 2 embodiment have a height which is greater than the width of the individual depletion control pillars 210, 210′ which are arranged in a row in the first direction. The depletion control pillars 210, 210′ are arranged in a geometric pattern with individual pillars, in the set of pillars 210 being arranged in a line extending in the first direction and the pillars 210′ being arranged in a second line extending in the first direction with the pillars in the sets 210, 210′ having the same or similar spacing from one another and from the nearest sidewall 217 or 217′ of the deep trench gate 208. In the FIG. 2 example, the depletion control pillars have a height which is greater than the width of the depletion control pillar in either the first direction or a second direction (left to right direction in FIG. 2) which is perpendicular to the first direction. The implementation shown in FIG. 2 results in an embodiment where a vertical type implementation of the capacitance control elements (e.g., depletion control pillars 210, 210′) and gate is used. Such an implementation is in contrast to the structure of the standard varactor shown in FIG. 1 where the gate is a layered structure which sits, for the most part, above the N well of the device shown in FIG. 1.

In some embodiments, including the one shown in FIG. 2, the depletion control pillars 210, 210′ are positioned at, or approximately halfway between, the nearest sidewall of the trench gate 217 or 217′ and the nearest N+ well pickup (204, 204′) which forms a wall along the side of the N well 206 or 206′.

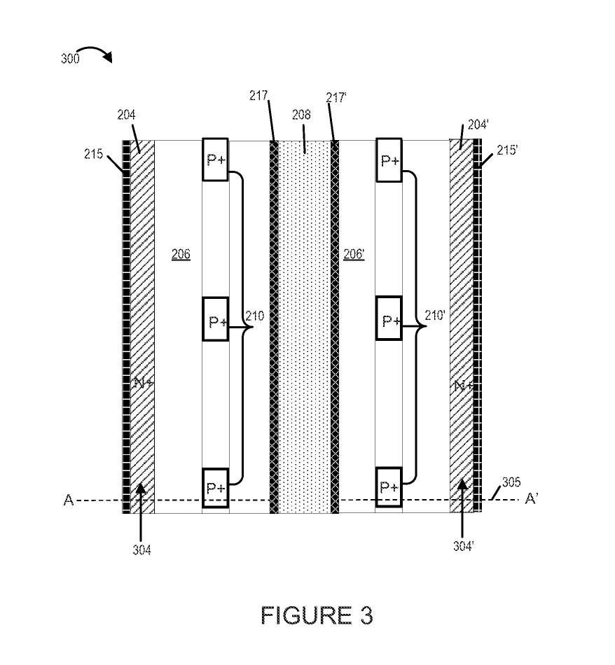

FIG. 3 shows a top view 300 of the device shown in FIG. 2. In the FIG. 3 illustration the dashed line 305 extending between A and A′ indicates the location to which the cross section of FIG. 2 corresponds. That is, FIG. 2 illustrates an angled view of a cross section of the device 200 taken along the line 305 shown in FIG. 3. Reference numbers shown in FIG. 3 which correspond to the elements previously discussed with regard to FIG. 2 are identified using the same reference numbers as used in FIG. 2 and will not be discussed in detail again.

The exemplary depletion control capacitor device 200 and the exemplary method of making the capacitor 200 involve various distinctive features that can, and in some embodiments does, provide improved characteristics compared to previously known variable capacitance devices.

In some embodiments the deep trench 208 is etched into the Buried oxide of SOI (Silicon of Insulator) substrate, CMOS or BiCMOS (Bipolar CMOS), or into existing N buried layer of a bulk BCD (Bipolar/CMOS/DMOS), or BiCMOS process. In various embodiments, the Liner oxide layer on the deep trench sidewalls, e.g., as shown using reference numbers 217, 217′, forms the oxide of the tunable capacitor 200. In various embodiments the liner oxide layer 214 extends in the direction in which the deep trench extends, e.g., in the first direction as well as vertically, and separates the first and second N well 206, 206′ from the contents of the deep trench gate 208. PoCl3 doped Poly Silicon is used to fill the deep trench 208 that is etched into the substrate, and CMP (Chemical Mechanical Polishing/Planarization) is used to planarize the surface, forming the gate electrode 208 in some implementations. Thus in some embodiments, PoCl3 doped Poly Silicon is used as the material to fill the deep trench 208 and forms the gate terminal.

The P doped pillars 210 are interspersed in sea of N region, e.g., such as in the N well 206 in the FIG. 2 embodiment.

In various embodiments, negative bias on P region, i.e., the Depletion control pins 210, 210′, with respect to the N region depletes the N region adjacent to Gate, i.e., the N well region 206, 206′, thereby lowering capacitance between Gate 208 and the N well region.

Compared to the standard CMOS varactor shown in FIG. 1, the exemplary 3 terminal depletion control capacitor shown in FIG. 2 has, at least in some embodiments, a significantly superior Tuning Ratio=Cmax/Cmin, for a given Q-factor.

Custom targeting of Tuning ratio vs Q factor achieved for a particular implementation can be achieved by the layout, e.g., location of N well pickup 204 relative to the deep trench sidewall 217 and/or the spacing between the P pillars, e.g., distance between the deep trench 208 sidewall 217 of the deep trench gate 208. For example, as the spacing between N well pickup and the sidewall 217 of the deep trench is increased the Q of factor of the device will suffer.

While the FIGS. 2 and 3 embodiment shows an example where an N well and N substrate are used in combination with P pillars, it should be appreciated that the same design could be implemented using elements of the opposite polarity.

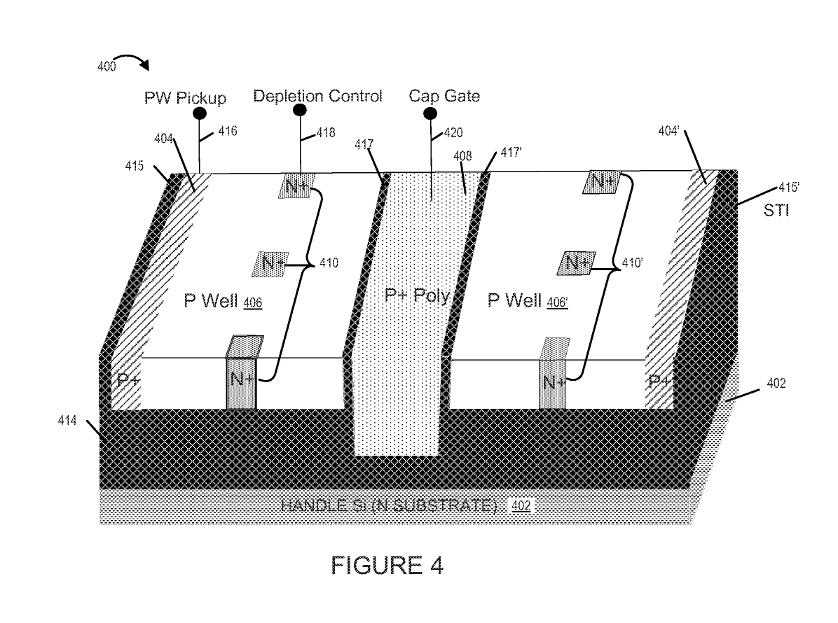

For example, FIG. 4 shows an embodiment wherein the 3 terminal device 400 uses the same or similar configuration to that shown in FIG. 2 but with the polarity of the components reversed. For example, in FIG. 4, the device 400 includes P wells 406, 406′, a P+ filled deep trench 408, P+ well pick ups 404, 404′ and an N substrate 402 instead of the similar elements in FIG. 2 which have the opposite polarity. In addition the mentioned elements, the FIG. 4 embodiment includes a P well pickup terminal 416 having an electrical connection with the P well pickup (404, 404′), a capacitance gate terminal 420 having an electrical connection with the contents of the P+ filled deep trench 408 and a depletion control terminal 418 in electrical connection with the N+ depletion control pillars 410, 410 which are interconnected with each other.

The substrate in the FIG. 4 embodiment and liner walls 415, 415′ and gate walls 417, 417′ are made of an oxide as in the case of the FIG. 2 embodiment. The material used for trench walls 417, 417′ may be the same oxide material used to line the substrate 402 or a different material.

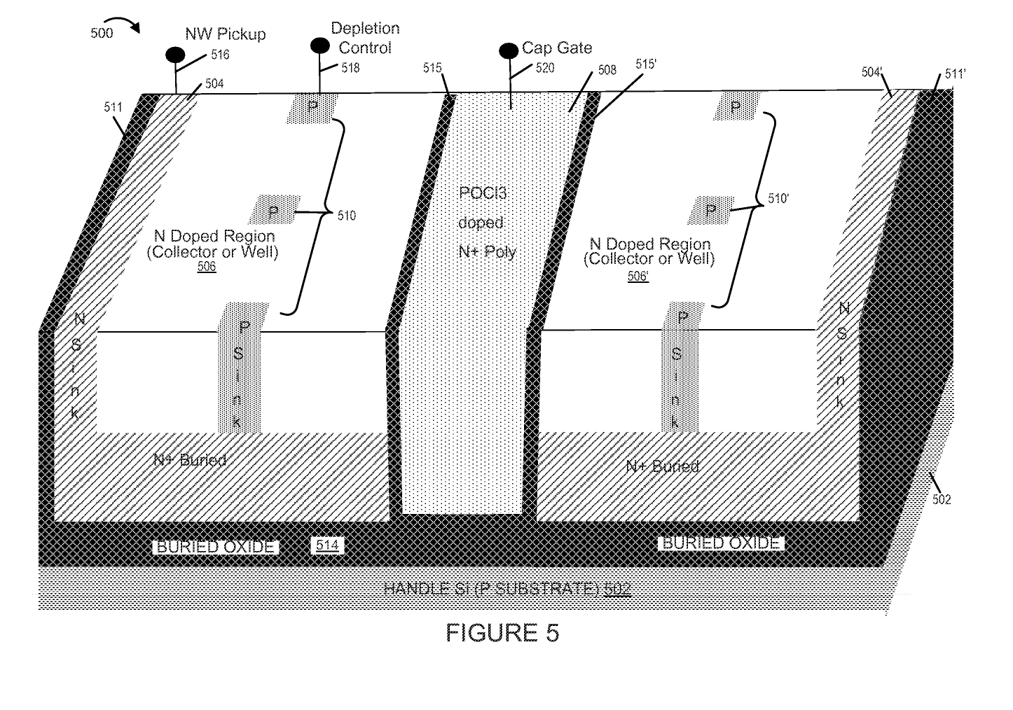

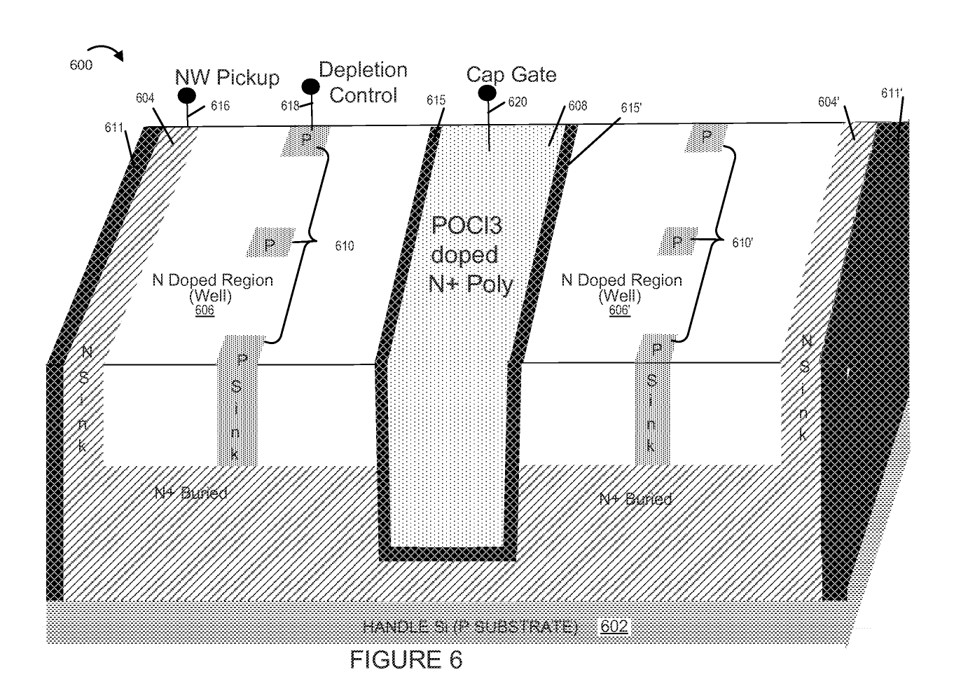

The general configuration of the 3 terminal controllable device described with regard to the FIGS. 2 and 4 implementations can be applied to other implementations, e.g., thick SOI implementations and implementations on bulk SI shown in FIGS. 5 and 6 respectively.

FIG. 5 illustrates an exemplary semiconductor device 500 which is an alternative embodiment of the semiconductor device shown in FIG. 2. The semiconductor device 500 is implemented on thick Silicon on Insulator (SOI) substrate, e.g. using a HV (high voltage) BiCMOS process.

Various structures such as the Nburied, Nsink, Psink and Deep trench which are easily created as part of the thick SOI HV BiCMOS (Silicon on Insulator High Voltage Bipolar-CMOS) process flow, are utilized in the FIG. 5 embodiment for tunable capacitor implementation. In this embodiment, deep trench 508 is etched into an N+ buried layer 504 generated as part of the BiCMOS manufacturing process. The liner oxide 515 on the deep trench 508 sidewalls form the oxide of the tunable capacitor. PoCl3 doped Poly Si fills the deep trench 508 and then in some embodiments polishing is performed. Thus the PoCl3 doped Poly Si fill and polish forms the trench gate 508 which is in electoral contact with the gate terminal 520. P sinks 510 and 510′ are used in the FIG. 5 embodiments as P doped pillars which serve as the depletion control pillars. The pillars 510 are in electrical contact with the depletion control terminal 51. The N sinks 504, 504′ are linked to N+ buried material which sits on the buried oxide substrate and which also extends up the oxide sidewalls 511, 511′ to form the well pickups 504, 504′ which are connected to well pickup terminal 516. It should be noted that the oxide material which forms the buried oxide layer 514 that separates the P substrate 502 from the N doped wells 506, 506′ is also used as the oxide layer 515, 515′ which separate the sidewalls of the trench gate 508 from the N doped regions in which the control pillars 510, 510′ are located.

As in the other embodiments the pillars 510, 510′ are arranged in a line, separated apart from one another, extending in the same direction as the trench gate 508 at or approximately halfway between the trench gate and the sidewall of the well pickup 504, 504′.

FIG. 6 illustrates another exemplary semiconductor device 600 which is an alternative embodiment to the semiconductor devices shown in FIGS. 2 and 5. The semiconductor device 600 is implemented on Bulk Silicon substrate 602, e.g., using BCD (Bipolar CMOS DMOS) or BiCMOS (Silicon on Insulator High Voltage Bipolar-CMOS) process.

Various structures such as the N+ buried area. N sink, and P sink are easily created as part of a normal bulk BCD or BiCMOS process flow and these elements are positioned and utilized in the FIG. 6 embodiment for a tunable capacitor implementation.

In the illustrated exemplary implementation, the deep trench 608 is etched into an N+ buried layer 604. The liner oxide walls 615, 615′ and oxide bottom of the deep trench 608 separates the N+ doped poly of the trench gate from the N doped regions 606, 606′ which form the N wells. The oxide layer on the bottom of the trench gate 608 isolates the trench gate from the N+ buried material that sits on the Si P substrate 602. During manufacture PoCl3 doped Poly Si fills the deep trench 608 and then in some embodiments polishing is performed. Capacitor gate 620 is in electrical contact with the N+ material which forms the gate trench 608. Thus the PoCl3 doped Poly Si fill and polish forms the gate electrode 620. The P sinks 610, 610′ which are used as the P doped control pillars which are connected to the depletion control terminal 618. The N sinks 604, 604′ which extend in the first direction parallel to the trench gate are linked to the N+ buried material and forms the N well pickups 604, 604′ which are connected to the well pickup terminal 616. The outside surface of the N sinks 604, 604′ are lined with eh oxide material also used to line the sidewalls of the trench gate 608 to form the structure shown in FIG. 6.

As with the FIG. 2 embodiment, the polarity of the elements in the FIGS. 5 and 6 embodiments can be reversed. e.g., with P elements being replaced by N elements. Numerous additional embodiments and variations on the exemplary 3 terminal variable capacitor devices are also possible.

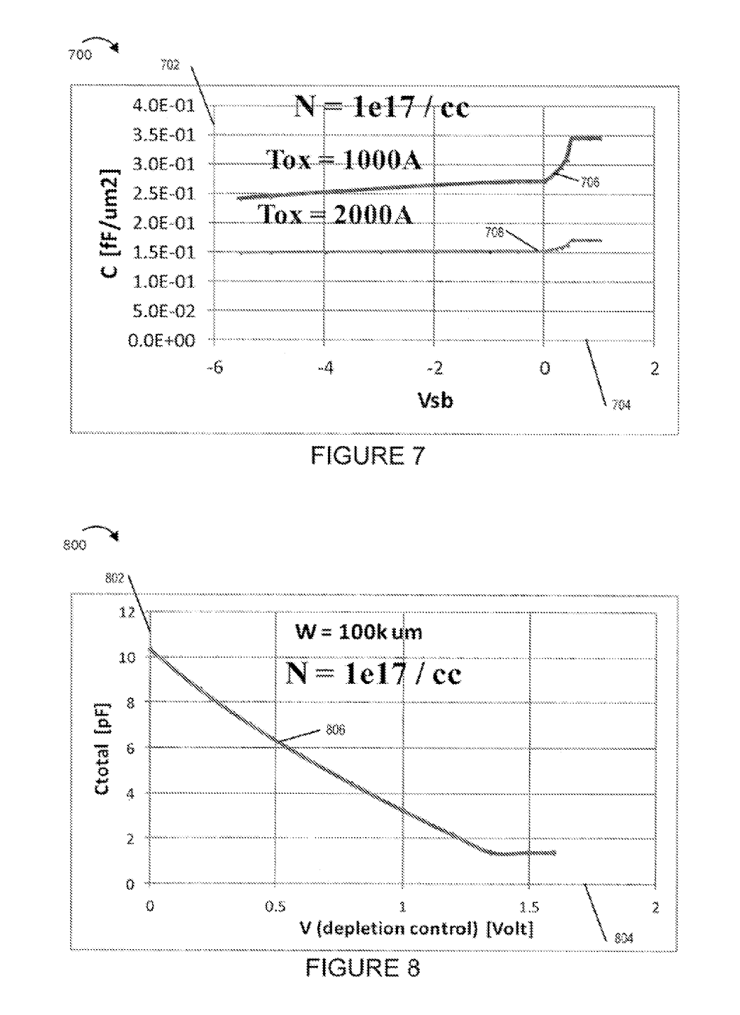

FIG. 7 is a drawing 700 illustrating a Capacitance versus Voltage (source-bulk voltage V_{SB}) plot for a standard NMOS-N Well Varactor. The capacitance is shown on the Y axis 702 and expressed in Femto Farad/micrometer² (fF/μm²) while the voltage is shown on the X-axis 704 and expressed in volts.

In the illustrated plot, the variation of capacitance with voltage is shown for two different oxide thicknesses (T_{OX}) and the doping concentration N is assumed to be N=1e17/cc. As illustrated in the plot 700, variation of capacitance with voltage for oxide thickness T_{OX}=1000 A is indicated by reference 706 while variation of capacitance with voltage for oxide thickness T_{OX}=2000 A is indicated by reference 708. The tuning ratio for the standard varactor for which the plot is shown is approximately equal to 1.

FIG. 8 is a drawing 800 illustrating a Capacitance versus Voltage (depletion control voltage) plot for an exemplary semiconductor device, e.g., a tunable depletion control capacitor such as the one illustrated in FIG. 2 example, in accordance with an exemplary embodiment. The total capacitance is shown on the Y axis 802 and expressed in Pico Farad (pF) while the voltage is shown on the X-axis 804 and expressed in volts.

In the illustrated plot, the variation of capacitance with voltage is shown for a given oxide thickness (T_{OX}), with the doping concentration N being assumed to be N=1e17/cc, and lateral depletion width=1 μm (1 micron). In the plot 800, variation of capacitance with voltage for an oxide thickness T_{OX}=1000 A is illustrated as indicated by reference 806. As should be appreciated, for the exemplary tunable depletion control capacitor analytical calculations indicate that the tuning ratio is significantly larger than that of a standard NMOS varactor. For example, calculations performed for the exemplary tunable depletion control capacitor for which the plot 800 is shown the tuning ratio is approximately =7.6, and the quality factor (Q)=148 at 2 GHz.

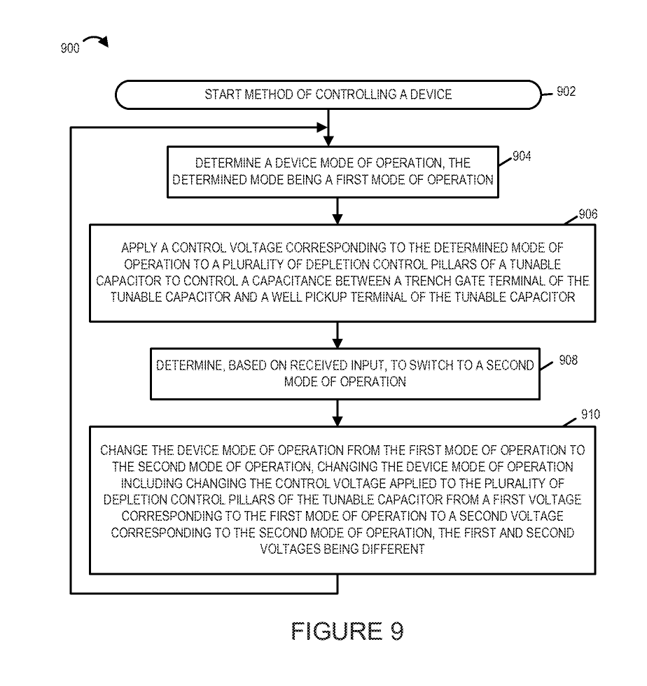

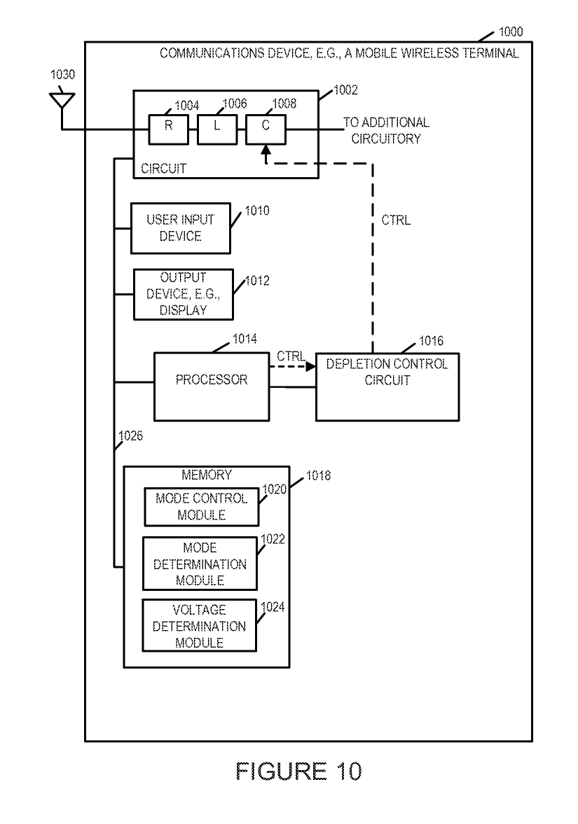

FIG. 9 is a flowchart 900 illustrating the steps of an exemplary method of controlling a device, in accordance with one exemplary embodiment. In some embodiments the device controlled by the method shown in FIG. 9 is the device 1000 shown in FIG. 10. In some embodiments the device is e.g., a wireless mobile communication device such as a wireless terminal. The device includes an exemplary tunable capacitor device with variable capacitance such as the tunable capacitor devices 200, 400, 500 and 600 discussed in FIGS. 2, 4, 5 and 6.

Operation starts in step 902. In step 902 the device is powered on and initialized. Operation proceeds from start step 902 to step 904. In step 904 a determination is made regarding the device mode of operation. For example, the device may select a particular mode of operation to be used based on the communications frequencies available, and/or communications protocols supported, in the region in which the device is located. In accordance with one aspect the device is a multi-mode device capable of operating in a plurality of modes where the modes correspond to use of different frequency bands and/or different communications technologies. For discussion purposes, consider that in step 904 it is determined that the device is to operate in a first mode, e.g., a mode in which a first frequency band is used for communications. In such a case it will be important that the devices antenna and/or related circuit are tuned for the frequency band to be used for the first mode of operation.

Operation proceeds from step 904 to step 906. In step 906 a control voltage, e.g., a first voltage, corresponding to the determined device mode of operation, e.g., first mode, is applied to a plurality of depletion control pillars of a tunable capacitor. This voltage may be predetermined with the voltage to be used specified by information stored in memory indicating a control voltage to be used for different modes of operation, e.g., a first control voltage for a first mode of operation and a second different control voltage for a second mode of operation. In some embodiments the tunable capacitor includes: a substrate; a trench gate supported by said substrate, said trench gate having a first depth and extending in a first direction; a well of a first polarity, said well extending in said first direction parallel to said trench gate; a well pickup, said well pickup being of said first polarity and being adjacent said well and extending in said first direction; and a plurality of depletion control pillars, said plurality of depletion control pillars being of a second polarity and being positioned in said well between said trench gate and said well pickup, said second polarity being different from said first polarity; and a trench gate terminal where the trench gate terminal is in contact with the trench gate of the capacitor.

For example, the control voltage used for the first mode may be applied to, e.g., pillars 210 of the tunable capacitor 200 to control a capacitance between a trench gate terminal (e.g., trench gate 208) of the tunable capacitor and a well pickup terminal (e.g., 216) of the tunable capacitor 200. As discussed earlier, the application of voltage on the depletion control terminal controls the capacitance of the tunable capacitor and thus the device that employs the tunable capacitor can operate in various modes depending on the desired capacitance as controlled by the voltage applied to the depletion control terminal of the variable capacitor.

Operation proceeds from step 906 to step 908. In step 908 it is determined based on received input, to switch the device's mode of operation from the first mode to a second mode, e.g., a communications mode in which a second frequency band is used for communications, the first and second modes being different. The input may be an interference signal, a received signal from a second base station using the second frequency band which is stronger than a received signal from a first base station using the first frequency band, a control signal from a base station, or user input specifying that the second communications mode of operation should be used instead of the first mode. The first and second modes may correspond to the same communications technology, e.g., CDMA or different communications technologies, e.g., CDMA and OFDM, respectively.

Operation proceeds from step 908 to step 910. Following the determination that device's mode of operation is to be changed in step 908, operation proceeds to step 910 in which the device's mode of operation is changed from the first mode of operation to the second mode of operation. This change involves changing the control voltage applied to the plurality of depletion control pillars of the tunable capacitor from the first voltage corresponding to the first mode of operation to a second voltage corresponding to the second mode of operation. The first and second voltages are different resulting in a change in the capacitance of the controllable capacitor making the capacitor suitable for use during the second mode of operation.

Following the application of the second voltage to the plurality of depletion control pillars, the device operates in second mode of operation, e.g., and communicates with other devices in the second frequency band. Operation proceeds from step 910 back to step 904 in some embodiments. As should be appreciated the device may switch between modes of operation as its position and/or channel conditions change with the control voltage being applied to the variable capacitor changing so that the capacitor provides the capacitance appropriate for the particular mode of operation.

FIG. 10 illustrates an exemplary communications device 1000, e.g. a wireless mobile terminal such as a user equipment (UE) device, that uses an exemplary tunable capacitor implemented in accordance with some embodiments. In various embodiments the communications device 1000 can be, and sometimes is, used to implement the method of flowchart 900.

The device 1000 includes a circuit 1002, e.g., an RLC circuit, a user input device 1010, an output device 1012, a processor 1014, a depletion control circuit 1016 and memory 1018 coupled together via a bus 1026 over which the various elements may interchange data and information. The user input device 1010 may be e.g., a keypad or another device that can be used to receive input from a user of the device 1000, e.g., input selecting a mode of operation or providing data to be communicated to another device. In some embodiments the output device 1012 is a display device and/or speaker.

The circuit 1002 includes an individual R (resistor) element 1004, an L (inductor) element 1006 and a C (capacitor) element 1008 which is e.g., a tunable capacitance device such as the device 200, 400, 500 and/or 600. The device 1000 further includes wireless communications antenna 1030 coupled to the circuit 1002 through which wireless signals may be received and/or transmitted. In some embodiments, the same antenna is used for both input and output wireless communications signaling and for communications in multiple, e.g., different, frequency bands. Memory 1018 includes routines and a plurality of modules including a mode control module 1020, a mode determination module 1022 and a voltage determination module 1024. The modules can, and in some embodiments are, implemented fully in hardware within the processor 1014, e.g., as individual circuits. In other embodiments some of the modules are implemented, e.g., as circuits, within the processor 1014 with other modules being implemented, e.g., as circuits, external to and coupled to the processor. Combinations of software and hardware are also possible for implementing the modules.

The processor 1014, in some embodiments, operating under control of the mode determination module 1022, determines the mode of communications operation to be used at a particular point in time, e.g., based on received signals and/or user input. When executed, mode control module 1020 causes the processor 1014 to configure the device 1000 to operate in accordance with the mode of operation, e.g., a first or second mode of operation, determined by the mode determination module 1022. Mode control module 1020 interacts with the voltage determination module 1024 which determines the control voltage to be supplied to the depletion control circuit 1016 for the mode of operation in which the device 1000 is to operate. The initial voltage setting for a mode of operation may be determined from a predetermined value stored in memory for the particular mode of operation with the voltage being adjusted, in some embodiments, based on feedback or other information to finely adjust and/or tune the RLC circuit 1002 for the particular mode of operation. The processor 1014 signals, via the control signal CTRL, to the depletion control circuit 1016, the voltage to applied to the depletion control terminal of the tunable capacitor 1008. In response to the control signal the depletion control circuit 1016 adjusts its voltage output to the appropriate level so that the depletion control terminal of the tunable capacitor 1008 is supplied with the control voltage to be used for the determined mode of operation. As the mode of operation is changed, the processor 1014 will signal the depletion control circuit 1016 to change the control voltage applied to the depletion control terminal of the tunable capacitor 1008.

While the RLC circuit 1002 is shown as a series RLC circuit, in some embodiments a parallel RLC circuit is used where the resistor 1004, inductor 1006, and tunable capacitor 1008 are arranged in parallel rather than in series. In such an embodiment the tunable capacitor 1008 is still controlled by application of a control voltage to the depletion control terminal of the capacitor while the other two terminals of the tunable capacitor, i.e., the gate and well pickup, are the terminals between which the capacitance is used and controlled.

Some of the features and advantages of the novel tunable three terminal capacitor devices implemented in accordance with various embodiments include one or more of the following:
i) significantly higher tuning ratio at a given quality factor, or vice versa, unlike conventional NMOS-on-NW or PMOS-on-PW varactors with thick oxide where tuning ratio is very poor (near unity);
ii) compatibility with thick oxide allowing the device to withstand large (˜+/−35V) voltage swings as required on many tunable antenna designs;
iii) easy integration of the variable capacitor into CMOS, BiCMOS or BCD processes on Bulk or SOT process flows allowing the variable capacitors to be easily integrated into a large number of semi-conductor devices and/or processors.

An exemplary process flow used in fabrication of an exemplary semiconductor device, e.g., the device of FIG. 2, includes the following sequence of operations:
Padox (Pattern dependent oxidation)
Pad nitride (Polymer assisted deposition of nitride)
ARC (Anti reflection coating)
Deep trench Mask
Nitride etch
Ash/Clean
Si trench etch (stop at BOX. e.g., perform etching and stop at buried oxide)
Aniso oxide etch (BOX) (timed etch)
Sac ox, etch (Sacrificial oxidation etching)
Liner ox
In-situ doped Poly dep (HSG(Hemispherical grained) poly dep condition for larger cap density)
Poly etchback
Nitride etch, Clean
The process flow may proceed from this point using standard CMOS process flow steps to produce a final semiconductor device, e.g., chip or other device including a tunable and/or variable capacitance device such as the semiconductor device shown in any of FIG. 2.

While the present application uses several terms and abbreviations that are well known in the semiconductor field, set forth below is list along with the corresponding meaning of at least some of the terms used in the present application:
Poly: Polycrystalline Silicon also referred to as Polysilicon or simply Poly
SOI: Silicon on Insulator
CMOS: Complementary metal-oxide-semiconductor
MOSFET: Metal-oxide-semiconductor field effect transistor
NMOS: n-channel MOSFET
PMOS: p-channel MOSFET
BiCMOS: Combination of Bipolar and CMOS technology, simply referred to as BiCMOS
HV BiCMOS: High Voltage BiCMOS process
BCD: Bipolar CMOS DMOS
BOX: Buried Oxide

The techniques of various embodiments may be implemented using software, hardware and/or a combination of software and hardware. For example, software may be used to in combination with hardware to control the voltage applied to the terminals of a capacitor device described herein so that the capacitance of the device corresponds to a desired mode of operation, e.g., transmission or receipt in a particular frequency band.

Various embodiments are directed to an electronic semiconductor device, e.g., a tunable capacitor. Various embodiments are also directed to methods, e.g., method of fabricating and/or manufacturing an electronic semiconductor device, e.g., a tunable capacitor and/or other electronic semiconductor device.

It is understood that the specific order or hierarchy of steps in the processes disclosed is an example of exemplary approaches. Based upon design preferences, it is understood that the specific order or hierarchy of steps in the processes may be rearranged while remaining within the scope of the present disclosure. The accompanying method claims present elements of the various steps in a sample order, and are not meant to be limited to the specific order or hierarchy presented.

In some embodiments, one or of the variable capacitance devices described here are included in a processor or processors, e.g., CPUs, of one or more devices, e.g., communications devices such as wireless terminals (UEs), and/or access nodes, e.g., base stations or wireless terminals. e.g., user equipment devices.

Various variations to the embodiments described above will be apparent to those skilled in the art in view of the above description. Such variations are to be considered within the scope. The methods and apparatus may be, and in various embodiments are, used with CDMA, orthogonal frequency division multiplexing (OFDM), and/or various other types of communications techniques which may be used to provide wireless communications links between devices.

What is claimed is:

1. A tunable capacitor comprising:
a substrate;
a trench gate supported by said substrate, said trench gate having a first depth and extending in a first direction;
a first well of a first polarity, said first well extending in said first direction parallel to said trench gate;
a first well pickup of said first polarity adjacent said first well and extending in said first direction; and
a first plurality of depletion control pillars of a second polarity positioned in said first well of first polarity between said trench gate and said first well pickup, said second polarity being different from said first polarity.

2. The tunable capacitor of claim 1, wherein said first polarity is negative (N) and said second polarity is positive (P).

3. The tunable capacitor of claim 1,
wherein said first well is a negative well (N well); and
wherein said first well pickup is a negative well (N well) pickup.

4. The tunable capacitor of claim 3,
wherein said trench gate is a N+ region,
wherein said depletion control pillars are P+ pillars; and
wherein said first well pickup is an N+ region.

5. The tunable capacitor of claim 1, wherein said depletion control pillars extend to a depth which is less than the depth of the trench gate.

6. The tunable capacitor of claim 1, wherein an individual depletion control pillar in said first plurality of depletion control pillars has a depth which is greater than the width of the individual depletion control pillar in the first direction.

7. The tunable capacitor of claim 6, wherein the depletion control pillars are electrically connected while being spaced apart from one another in the first direction by a distance at least as wide as the width of the depletion control pillar in the first direction.

8. The tunable capacitor of claim 1, wherein said depletion control pillars are positioned in said first well at or approximately halfway between said trench gate and said first well pickup.

9. The tunable capacitor of claim 1, further comprising:
a capacitor gate terminal coupled to said trench gate;
a depletion control terminal coupled to at least one depletion control pillar in said first plurality of depletion control pillars; and
a well pickup terminal coupled to said first well pickup of first polarity.

10. The tunable capacitor of claim 9, wherein said first plurality of depletion control pillars include depletion control pillars that are spaced apart from one another forming a row of depletion control pillars extending in said first direction.

11. The tunable capacitor of claim 10, further comprising:
a first liner oxide layer extending in said first direction and separating said first well region from said trench gate.

12. The tunable capacitor of claim 10, further comprising:
a second well of said first polarity extending in said first direction parallel to said trench gate;
a second well pickup adjacent said second well and extending in said first direction; and
a second plurality of depletion control pillars of said second polarity positioned in said second well region between said trench gate and said second well pickup.

13. The tunable capacitor of claim 12, wherein both sides of said trench gate which extend in said first direction are lined by a liner oxide which separates said trench gate from said first and second wells.

14. The tunable capacitor of claim 9,
wherein said substrate is an SOI substrate;
wherein said trench gate is a POCL3 doped N+ region;
wherein said depletion control pillars are P+ doped regions; and
wherein said first well pickup is an N+ doped region.

15. The tunable capacitor of claim 14, wherein said first well pickup has a second depth, said first depth being greater than said second depth, said trench gate extending into an oxide layer of said substrate.

16. The tunable capacitor of claim 9,
wherein said substrate is a thick SOI substrate;
wherein said trench gate is a POCL3 doped N+ region;
wherein said depletion control pillars are P regions; and
wherein said first well pickup is an N sink region.

17. The tunable capacitor of claim 9,
wherein said substrate is a Si substrate;
wherein said trench gate is a POCL3 doped N+ region;
wherein said depletion control pillars are P regions; and
wherein said first well pickup is an N sink region.

18. A method of controlling a device, the method comprising:
determining a device mode of operation;
applying a control voltage corresponding to said determined mode of operation to a plurality of depletion control pillars of a tunable capacitor to control a capacitance between a trench gate terminal of said tunable capacitor and a well pickup terminal of said tunable capacitor, said tunable capacitor including:
a substrate;
a trench gate supported by said substrate, said trench gate having a first depth and extending in a first direction;
a well of a first polarity, said well extending in said first direction parallel to said trench gate;
a well pickup, said well pickup being of said first polarity and being adjacent said well and extending in said first direction; and
said plurality of depletion control pillars, said plurality of depletion control pillars being of a second polarity and being positioned in said well between said trench gate and said well pickup, said second polarity being different from said first polarity; and
said trench gate terminal, said trench gate terminal being in contact with said trench gate.

19. The method of claim 18, further comprising:
changing the device mode of operation from a first mode of operation to a second mode of operation, said changing including changing the control voltage applied to the plurality of depletion control pillars of the tunable capacitor from a first voltage corresponding to the first mode of operation to a second voltage corresponding to the second mode of operation, said first and second voltages being different.

20. The method of claim 19,
wherein said device is a communications device;
wherein said first mode of operation is a first communications mode of operation in which communications is implemented in a first frequency band; and
wherein said second mode of operation is a second communications mode of operation in which communications is implemented in a second frequency band, said first and second frequency bands being different.
